(19) United States
(12) Patent Application Publication
(10) Pub. No.: US 2020/0336157 A1
(43) Pub. Date: Oct. 22, 2020

(54) SYSTEMATIC AND XOR-BASED CODING TECHNIQUE FOR DISTRIBUTED STORAGE SYSTEMS

(71) Applicant: MEMOSCALE AS, Trondheim (NO)

(72) Inventors: Rune E. JENSEN, Trondheim (NO); Sindre Berg STENE, Trondheim (NO)

(21) Appl. No.: 16/756,417

(22) PCT Filed: Oct. 16, 2018
(86) PCT No.: PCT/EP2018/078271

§ 371 Date: Apr. 15, 2020

(30) Foreign Application Priority Data
Oct. 16, 2017 (GB) 1716967.3

(51) Int. Cl. H03M 13/29; H03M 13/00; H03M 13/37; H03M 13/03; H03M 13/13

(52) U.S. Cl. CPC H03M 13/2942; H03M 13/616; H03M 13/13; H03M 13/036; H03M 13/3761

(57) ABSTRACT

Disclosed herein is a method for determining how to encode data in accordance with a systematic coding technique and encoding data in accordance with the determined systematic coding technique, the method comprising: determining the code parameters n, k, r and B, wherein n is the total number of nodes, k is the total number of nodes of source data, r is the total number of nodes of redundant data, such that n=k+r, B is the number of substripes of data in each of the nodes such that all of the nodes of source data and all of the nodes of redundant data comprise the same number of substripes, wherein k is 2 or more and B is 3 or more; determining nodes of source data that comprise source data that is not encoded by the systematic coding technique, wherein all of the B substripes in the nodes of source data store binary values only; and for each of the substripes of each of the nodes of redundant data, determining to generate the substripe of redundant data in dependence on a generator matrix; and encoding substripes of redundant data in accordance with the determined systematic coding technique by combining a plurality of substripes of the nodes of source data using XOR operations only; wherein the generator matrix comprises a plurality of tiles, with each of the tiles corresponding to one of the plurality of source nodes, wherein each tile is a B by B data structure comprising binary values only and at least one of the tiles is not a representation of a number in GF(2\hat{ }B).

### FIELD

The field of the invention is the systematic coding of data. A particularly advantageous application for coded data according to embodiments is in a data storage system. Embodiments provide an erasure coding technique that, for a given number of redundant nodes, allows a larger number of source nodes to be supported than with Reed-Solomon coding.

### BACKGROUND

Data centres that provide an easily accessible store of data are a necessary resource for many entities. The amount of data stored in a data centre may be in the order of multiple petabytes. It is normal for a data centre to be built from a plurality of separate data storage units to provide a data centre with expandable capacity and so that different parts of the data storage centre can be maintained independently. All, or part of, each of these data storage units may occasionally be offline due to a failure occurring or the data storage unit deliberately being taken offline for maintenance. The data is therefore preferably stored in such a way that it is still accessible when any of the data storage units for storing the data are offline. A known technique is to store the data in a replicated manner. That is to say, the same data stored in a data storage unit is also stored in one or more other, separate, data storage units. This approach allows fast retrieval of data from a back-up data storage unit if one of the primary data storage units is offline.

A problem with storing data in a replicated manner is that the demand on data storage capacity is greatly increased and this increases costs. To solve this problem, it is known to use erasure codes for data storage. Using erasure codes for data storage requires additional processing to reconstruct unavailable data. However, the data storage requirements are a lot lower than those of replication systems. Reed-Solomon codes are well known error correcting codes that can be used as erasure codes for data storage. For a systematic implementation of a Reed-Solomon code as an erasure code, data is coded into a plurality of source data nodes, k, and a plurality of redundant data nodes, r, the total number of data nodes, n, being k+r. The source and redundant data nodes may be stored in a plurality of different data storage units, the data storage units each storing one or more data nodes. Due to the reconstruction properties of Reed-Solomon codes, if any r of the n data nodes are unavailable due to their data storage unit being offline, then the same data that is stored in the r data nodes can still be obtained through processing performed on data obtained from a plurality of the other data nodes. That is to say, (n-r) data nodes that are available can be used to reconstruct the r data nodes that are unavailable. The processing to reconstruct one or more of the r data nodes may be performed at a processor that is separate from the nodes. Alternatively, the processing to reconstruct one or more of the r data nodes may be performed at the nodes.

A number of other coding techniques than Reed-Solomon are suitable for such data reconstructions. If the coding technique has the capability that any k nodes are able to reconstruct all of the source data nodes, the coding technique is Maximum Distance Separable, MDS.

It is highly preferable for the stored data to be coded systematically. This allows stored source data to be read directly from a data storage unit, without any processing being required to reconstruct the source data, if the data storage unit storing the source data is online.

There is a general need to improve known coding techniques.

### SUMMARY

According to a first aspect of the invention, there is provided a method for determining how to encode data in accordance with a systematic coding technique and encoding data in accordance with the determined systematic coding technique, the method comprising: determining the code parameters n, k, r and B, wherein n is the total number of nodes, k is the total number of nodes of source data, r is the total number of nodes of redundant data, such that n=k+r, B is the number of substripes of data in each of the nodes such that all of the nodes of source data and all of the nodes of redundant data comprise the same number of substripes, wherein k is 2 or more and B is 3 or more; determining nodes of source data that comprise source data that is not encoded by the systematic coding technique, wherein all of the B substripes in the nodes of source data store binary values only; and for each of the substripes of each of the nodes of redundant data, determining to generate the substripe of redundant data in dependence on a generator matrix; and encoding substripes of redundant data in accordance with the determined systematic coding technique by combining a plurality of substripes of the nodes of source data using XOR operations only; wherein the generator matrix comprises a plurality of tiles, with each of the tiles corresponding to one of the plurality of source nodes, wherein each tile is a B by B data structure comprising binary values only and at least one of the tiles is not a representation of a number in GF(2\hat{ }B).

Preferably, said at least one of the tiles that is not a representation of a number in GF(2\hat{ }B) comprises values that determine to generate one of the redundant nodes in dependence on exactly eleven substripes of source data.

Preferably, said at least one of the tiles that is not a representation of a number in GF(2\hat{ }B) comprises values that determine to generate at least one of the substripes of redundant data in dependence on a larger number of substripes of source data than the maximum number of substripes of source data that a substripe of redundant data can be determined to be generated in dependence on by a different generator matrix that entirely consists of tiles of binary values with each of the tiles being a representation of a number in GF(2\hat{ }B).

Preferably, the total number of substripes of source data that all of the substripes of redundant data are generated in dependence on is larger than the maximum number of substripes of source data that all of the substripes of redundant data can be determined to be generated in dependence on by a different generator matrix that entirely consists of tiles of binary values with each of the tiles being a representation of a number in GF(2\hat{ }B).

According to a second aspect of the invention, there is provided a method for determining how to encode data in accordance with a systematic coding technique and encoding data in accordance with the determined systematic coding technique, the method comprising: determining the code parameters n, k, r and B, wherein n is the total number of nodes, k is the total number of nodes of source data, r is the total number of nodes of redundant data, such that n=k+r, B is the number of substripes of data in each of the nodes such that all of the nodes of source data and all of the nodes of redundant data comprise the same number of substripes, wherein k is 2 or more and B is 3 or more; determining nodes of source data that comprise source data that is not encoded by the systematic coding technique, wherein all of the B substripes in the nodes of source data store binary values only; and for each of the substripes of each of the nodes of redundant data, determining to generate the substripe of redundant data in dependence on a generator matrix; and encoding substripes of redundant data in accordance with the determined systematic coding technique by combining a plurality of substripes of the nodes of source data using XOR operations only; wherein, for at least one of the nodes of redundant data, the node of redundant data is generated in dependence on exactly eleven substripes of source data.

According to a third aspect of the invention, there is provided a method for determining how to encode data in accordance with a systematic coding technique and encoding data in accordance with the determined systematic coding technique, the method comprising: determining the code parameters n, k, r and B, wherein n is the total number of nodes, k is the total number of nodes of source data, r is the total number of nodes of redundant data, such that n=k+r, B is the number of substripes of data in each of the nodes such that all of the nodes of source data and all of the nodes of redundant data comprise the same number of substripes, wherein k is 2 or more and B is 3 or more; determining nodes of source data that comprise source data that is not encoded by the systematic coding technique, wherein all of the B substripes in the nodes of source data store binary values only; and for each of the substripes of each of the nodes of redundant data, determining to generate the substripe of redundant data in dependence on a generator matrix; and encoding substripes of redundant data in accordance with the determined systematic coding technique by combining a plurality of substripes of the nodes of source data using XOR operations only; wherein, for at least one of the substripes of redundant data, the substripe of redundant data is generated in dependence on a larger number of substripes of source data than the maximum number of substripes of source data that a substripe of redundant data can be determined to be generated in dependence on by a different generator matrix that entirely consists of tiles of binary values with each of the tiles being a representation of a number in GF(2\hat{ }B).

According to a fourth aspect of the invention, there is provided a method for determining how to encode data in accordance with a systematic coding technique and encoding data in accordance with the determined systematic coding technique, the method comprising: determining the code parameters n, k, r and B, wherein n is the total number of nodes, k is the total number of nodes of source data, r is the total number of nodes of redundant data, such that n=k+r, B is the number of substripes of data in each of the nodes such that all of the nodes of source data and all of the nodes of redundant data comprise the same number of substripes, wherein k is 2 or more and B is 3 or more; determining nodes of source data that comprise source data that is not encoded by the systematic coding technique, wherein all of the B substripes in the nodes of source data store binary values only; and for each of the substripes of each of the nodes of redundant data, determining to generate the substripe of redundant data in dependence on a generator matrix; and encoding substripes of redundant data in accordance with the determined systematic coding technique by combining a plurality of substripes of the nodes of source data using XOR operations only; wherein the total number of substripes of source data that all of the substripes of redundant data are generated in dependence on is larger than the maximum number of substripes of source data that all of the substripes of redundant data can be determined to be generated in dependence on by a different generator matrix that entirely consists of tiles of binary values with each of the tiles being a representation of a number in GF(2\hat{ }B).

Preferably, B=4.

Preferably:

k≤15, preferably k=15;
r is 2 or 3; and the tiles are dependent on any k columns and any r rows of:

| | | | | | | | | | | | | | | |
|---|---|---|---|---|---|---|---|---|---|---|---|---|---|---|
| 1000 | 1000 | 1000 | 1000 | 1000 | 1000 | 1000 | 1000 | 1000 | 1000 | 1000 | 1000 | 1000 | 1000 | 1000 |
| 0100 | 0100 | 0100 | 0100 | 0100 | 0100 | 0100 | 0100 | 0100 | 0100 | 0100 | 0100 | 0100 | 0100 | 0100 |
| 0010 | 0010 | 0010 | 0010 | 0010 | 0010 | 0010 | 0010 | 0010 | 0010 | 0010 | 0010 | 0010 | 0010 | 0010 |
| 0001 | 0001 | 0001 | 0001 | 0001 | 0001 | 0001 | 0001 | 0001 | 0001 | 0001 | 0001 | 0001 | 0001 | 0001 |
| 1000 | 0100 | 1100 | 0010 | 1010 | 0110 | 1110 | 0001 | 1001 | 0101 | 1101 | 0011 | 1011 | 0111 | 1111 |
| 0100 | 1100 | 1000 | 0001 | 0101 | 1101 | 1001 | 0011 | 0111 | 1111 | 1011 | 0010 | 0110 | 1110 | 1010 |
| 0010 | 0001 | 0011 | 0110 | 0100 | 0111 | 0101 | 1101 | 1111 | 1100 | 1110 | 1011 | 1001 | 1010 | 1000 |
| 0001 | 0011 | 0010 | 1101 | 1100 | 1110 | 1111 | 1011 | 1010 | 1000 | 1001 | 0110 | 0111 | 0101 | 0100 |
| 1000 | 1100 | 0100 | 0110 | 1110 | 1010 | 0010 | 1011 | 0011 | 0111 | 1111 | 1101 | 0101 | 0001 | 1001 |
| 0100 | 1000 | 1100 | 1101 | 1001 | 0101 | 0001 | 0110 | 0010 | 1110 | 1010 | 1011 | 1111 | 0011 | 0111 |
| 0010 | 0011 | 0001 | 0111 | 0101 | 0100 | 0110 | 1001 | 1011 | 1010 | 1000 | 1110 | 1100 | 1101 | 1111 |
| 0001 | 0010 | 0011 | 1110 | 1111 | 1100 | 1101 | 0111 | 0110 | 0101 | 0100 | 1001 | 1000 | 1011 | 1010 |

wherein each column of tiles corresponds to a different one of the source nodes and each row of tiles corresponds to a different one of the redundant nodes.

Preferably:

k≤13, preferably k=13;
2≤r≤4; and the tiles are dependent on any k columns and any r rows of:

| | | | | | | | | | | | | |
|---|---|---|---|---|---|---|---|---|---|---|---|---|
| 1000 | 1000 | 1000 | 1000 | 1000 | 1000 | 1000 | 1000 | 1000 | 1000 | 1000 | 1000 | 1000 |
| 0100 | 0100 | 0100 | 0100 | 0100 | 0100 | 0100 | 0100 | 0100 | 0100 | 0100 | 0100 | 0100 |
| 0010 | 0010 | 0010 | 0010 | 0010 | 0010 | 0010 | 0010 | 0010 | 0010 | 0010 | 0010 | 0010 |
| 0001 | 0001 | 0001 | 0001 | 0001 | 0001 | 0001 | 0001 | 0001 | 0001 | 0001 | 0001 | 0001 |
| 1000 | 0100 | 1100 | 0010 | 1010 | 0110 | 1110 | 0001 | 1001 | 0101 | 1101 | 0011 | 1011 |
| 0100 | 1100 | 1000 | 0001 | 0101 | 1101 | 1001 | 0011 | 0111 | 1111 | 1011 | 0010 | 0110 |
| 0010 | 0001 | 0011 | 0110 | 0100 | 0111 | 0101 | 1101 | 1111 | 1100 | 1110 | 1011 | 1001 |
| 0001 | 0011 | 0010 | 1101 | 1100 | 1110 | 1111 | 1011 | 1010 | 1000 | 1001 | 0110 | 0111 |
| 1000 | 1110 | 1011 | 0001 | 0011 | 1100 | 0101 | 0111 | 1010 | 1101 | 0110 | 0100 | 0010 |
| 0100 | 1001 | 0110 | 0011 | 0010 | 1000 | 1111 | 1110 | 0101 | 1011 | 1101 | 1100 | 0001 |
| 0010 | 0101 | 1001 | 1101 | 1011 | 0011 | 1100 | 1010 | 0100 | 1110 | 0111 | 0001 | 0110 |
| 0001 | 1111 | 0111 | 1011 | 0110 | 0010 | 1000 | 0101 | 1100 | 1001 | 1110 | 0011 | 1101 |
| 1000 | 0011 | 0110 | 1011 | 1001 | 1101 | 0100 | 0010 | 1111 | 1110 | 0101 | 1010 | 1100 |
| 0100 | 0010 | 1101 | 0110 | 0111 | 1011 | 1100 | 0001 | 1010 | 1001 | 1111 | 0101 | 1000 |
| 0010 | 1011 | 0111 | 1001 | 1111 | 1110 | 0001 | 0110 | 1000 | 0101 | 1100 | 0100 | 0011 |
| 0001 | 0110 | 1110 | 0111 | 1010 | 1001 | 0011 | 1101 | 0100 | 1111 | 1000 | 1100 | 0010 |

wherein each column of tiles corresponds to a different one of the source nodes and each row of tiles corresponds to a different one of the redundant nodes.

Preferably:

k≤13, preferably k=13;
2≤r≤5; and the tiles are dependent on any k columns and any r rows of:

| | | | | | | | | | | | |
|---|---|---|---|---|---|---|---|---|---|---|---|
| 1000 | 1000 | 1000 | 1000 | 1000 | 1000 | 1000 | 1000 | 1000 | 1000 | 1000 | 1000 |
| 0100 | 0100 | 0100 | 0100 | 0100 | 0100 | 0100 | 0100 | 0100 | 0100 | 0100 | 0100 |
| 0010 | 0010 | 0010 | 0010 | 0010 | 0010 | 0010 | 0010 | 0010 | 0010 | 0010 | 0010 |
| 0001 | 0001 | 0001 | 0001 | 0001 | 0001 | 0001 | 0001 | 0001 | 0001 | 0001 | 0001 |
| 1000 | 0100 | 1100 | 0010 | 1010 | 0110 | 1110 | 0001 | 1001 | 0101 | 1101 | 0011 |
| 0100 | 1100 | 1000 | 0001 | 0101 | 1101 | 1001 | 0011 | 0111 | 1111 | 1011 | 0010 |
| 0010 | 0001 | 0011 | 0110 | 0100 | 0111 | 0101 | 1101 | 1111 | 1100 | 1110 | 1011 |
| 0001 | 0011 | 0010 | 1101 | 1100 | 1110 | 1111 | 1011 | 1010 | 1000 | 1001 | 0110 |
| 1000 | 0011 | 0110 | 1011 | 1001 | 1101 | 0100 | 0010 | 1111 | 1110 | 0101 | 1010 |
| 0100 | 0010 | 1101 | 0110 | 0111 | 1011 | 1100 | 0001 | 1010 | 1001 | 1111 | 0101 |
| 0010 | 1011 | 0111 | 1001 | 1111 | 1110 | 0001 | 0110 | 1000 | 0101 | 1100 | 0100 |
| 0001 | 0110 | 1110 | 0111 | 1010 | 1001 | 0011 | 1101 | 0100 | 1111 | 1000 | 1100 |
| 1000 | 1110 | 1011 | 0001 | 0011 | 1100 | 0101 | 0111 | 1010 | 1101 | 0110 | 0100 |
| 0100 | 1001 | 0110 | 0011 | 0010 | 1000 | 1111 | 1110 | 0101 | 1011 | 1101 | 1100 |
| 0010 | 0101 | 1001 | 1101 | 1011 | 0011 | 1100 | 1010 | 0100 | 1110 | 0111 | 0001 |
| 0001 | 1111 | 0111 | 1011 | 0110 | 0010 | 1000 | 0101 | 1100 | 1001 | 1110 | 0011 |
| 1000 | 0110 | 0111 | 1111 | 0101 | 0001 | 1100 | 1001 | 1110 | 1011 | 0010 | 1101 |
| 0100 | 1101 | 1110 | 1010 | 1111 | 0011 | 1000 | 0111 | 1001 | 0110 | 0001 | 1011 |
| 0010 | 0111 | 1010 | 1000 | 1100 | 1101 | 0011 | 1111 | 0101 | 1001 | 0110 | 1110 |
| 0001 | 1110 | 0101 | 0100 | 1000 | 1011 | 0010 | 1010 | 1111 | 0111 | 1101 | 1001 |

wherein each column of tiles corresponds to a different one of the source nodes and each row of tiles corresponds to a different one of the redundant nodes.

According to a fifth aspect of the invention, there is provided a method of generating coded data from source data, the method being equivalent to generating the coded data in dependence on any of the previous aspects.

Preferably, the method is computer-implemented.

According to a sixth aspect of the invention, there is provided a generator matrix for defining how to generate coded data from source data, the generator matrix defining a code that is equivalent to a code that has been generated by the method according to any of the previous aspects.

According to a seventh aspect of the invention, there is provided a method of decoding coded data, the method comprising decoding coded data that has been coded according to the method according to any of the first to fifth aspects.

Preferably, the method comprises recovering source data and/or redundant data by performing XOR operations only.

Preferably, the method further comprises storing the redundant data in a data storage system.

Preferably, the method is computer-implemented.

According to a eighth aspect of the invention, there is provided a computing system configured to perform the method according to any of the first, second, third, fourth, fifth and seventh aspects.

Preferably, the computing system comprises a data storage system; and the data storage system comprises a plurality of nodes for storing source and redundant data.

Preferably, the computing system further comprises a data processing system, wherein the data processing system is separate from the data storage system; and the processing performed to generate and/or recover source data and/or redundant data is performed in the data processing system.

According to a ninth aspect of the invention, there is provided a method for determining how to encode data in accordance with a systematic coding technique and encoding data in accordance with the determined systematic coding technique, the method comprising: determining the code parameters n, k, r and B, wherein n is the total number of nodes, k is the total number of nodes of source data, r is the total number of nodes of redundant data, such that n=k+r, B is the number of substripes of data in one of the nodes and each of the nodes of source data and nodes of redundant data comprise the same number of substripes, wherein B is 2 or more; determining nodes of source data that comprise source data that is not encoded by the systematic coding technique, wherein all of the B substripes in the nodes of source data store binary values only; for each of the substripes of the nodes of redundant data, determining to generate the substripe of redundant data in dependence on a combination of one or more substripes of source data, wherein the combination is dependent on tiles of the source nodes, each tile is a B by B matrix comprising binary values only and at least one of the tiles is not a representation of a number in GF(2\hat{ }B); and encoding the redundant data in accordance with the determined systematic coding technique by XOR operations only.

### LIST OF FIGURES

FIG. 1 shows part of a generator matrix of a coding technique according to an embodiment;

FIG. 2 shows part of a generator matrix of a coding technique according to an embodiment;

FIG. 3 shows part of a generator matrix of a coding technique according to an embodiment; and

FIG. 4 is a flowchart showing a process according to an embodiment.

### DESCRIPTION

When using systematic erasure codes, source data is stored in source data nodes without erasure coding being applied to it. Redundant data is stored in redundant data nodes. The redundant data is generated in dependence on the source data. If any one of the source data nodes is lost, or for any reason is unavailable, then the source data in the unavailable node can be recovered in dependence on the other source data nodes and the redundant nodes.

Embodiments provide a new systematic coding technique. The codes according to embodiments are constructed by dividing each source and redundant node into a plurality of substripes. Substripes may be alternatively referred to as subpackets.

Embodiments provide a new way of determining how each redundant node is generated in dependence on source data that improves on systematic Reed-Solomon (RS) erasure coding. With codes according to embodiments, all of the calculations for generating redundant data and recovering an unavailable node can be performed with only bitwise XOR operations. No calculations that cannot be performed by bitwise XOR operations are required.

Embodiments provide a systematic coding technique. According to embodiments, the nodes are divided into a plurality of substripes, i.e. B substripes where B is an integer greater than one. The source data is stored in each source node in a binary form and is therefore operable on using bitwise XOR operations.

The coding technique according to embodiments is defined by a generator matrix. The generator matrix has respective groups of B rows for each of the source and redundant nodes. B is the number of substripes that each node is divided into and is a number greater than one. The number of source nodes is k, the number of redundant nodes is r and the total number of nodes is n, where n=k+r. The number of rows of the generator matrix is therefore (n×B), i.e. the product of n and B. Each group of B consecutive rows corresponds to the same node, with the generator matrix having a value for each of the B substripes in the node.

The number of columns of the generator matrix is (k×B), i.e. the product of k and B. Each group of B consecutive columns corresponds to a different one of the source nodes. For each group of B columns for the same node, the generator matrix has a value for each of the B substripes in the node

The values in the generator matrix are arranged in a plurality of tiles, where each tile is a B by B square data structure, i.e. matrix. The B rows of each tile are consecutive rows that all correspond to the same node. The B columns of each tile are consecutive columns that all correspond to the same node, which may be the same or different from the node that the rows of the tile correspond to.

The generator matrix contains only the binary values ‘1’ and ‘0’. The binary values in each row of the generator matrix define which of the substripes in the source nodes are combined with each other to generate the node that corresponds to that row. The value ‘1’ in a column of the generator matrix indicates that the substripe of the node that the row containing the value corresponds to is generated in dependence on the substripe identified by the column. The value ‘0’ in a column of the generator matrix indicates that the substripe of the node that the row containing the value corresponds to is not generated in dependence on the substripe identified by the column.

The part of the generator matrix that defines the source nodes corresponds to the k by k identity matrix, i.e. there is only one ‘1’ in each row, since the coding technique is systematic.

The part of the generator matrix that defines the redundant nodes may comprise more than one ‘1’ value in each row since each redundant node comprises at least one combination of data in the source nodes. Each of the ‘1’ values in a row of the generator matrix identifies the substripes of source data that are combined to generate the substripe of a redundant node that the row corresponds to. The combination of substripes of source data to generate a substripe of redundant data is performed by using the bitwise XOR operation.

By using only the XOR operation on data, the operations on the source data to encode the redundant data and/or recover a node can be performed very efficiently. In addition, when only XOR operations are required, it is easier to apply optimisation processes on the code.

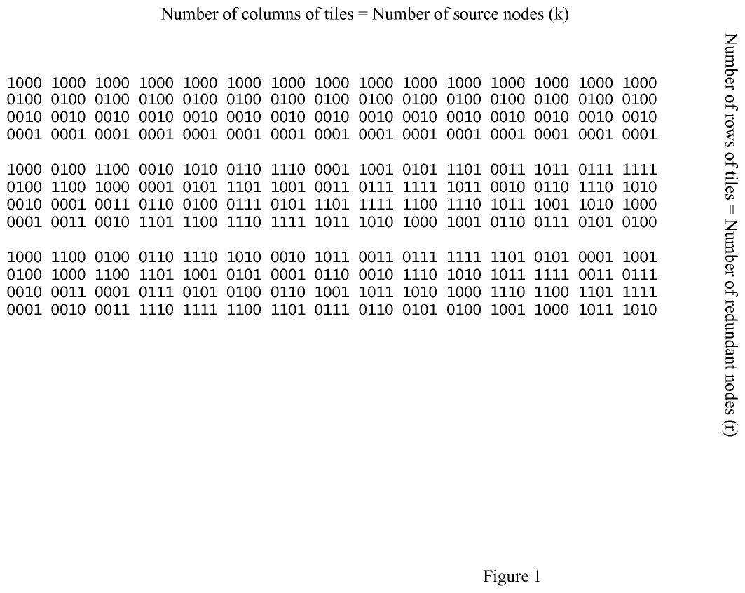

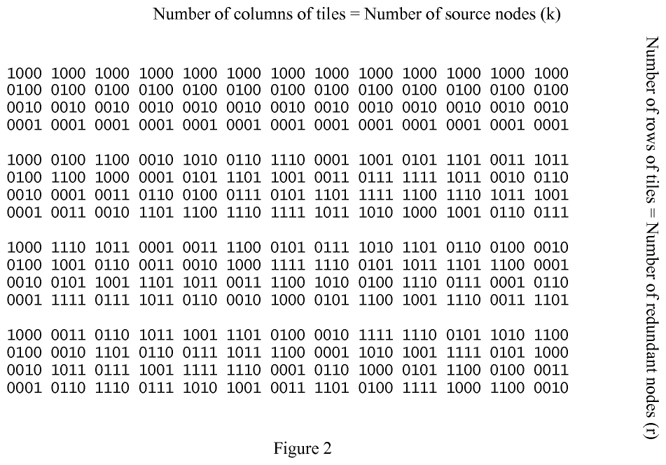

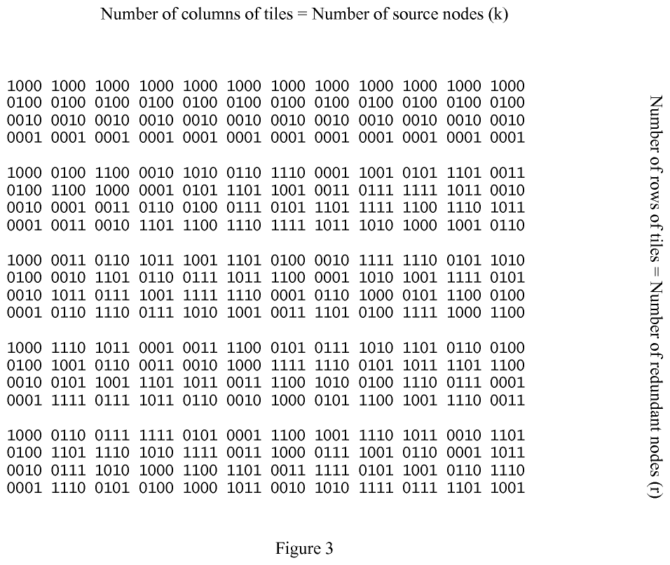

Particularly advantageous codes according to embodiments that have been discovered by the inventors are shown in FIGS. 1 to 3. FIGS. 1 to 3 show the part of a generator matrix that defines how the redundant nodes are generated. The part of the generator matrix that defines how the source nodes are generated is not shown since this part of the generator matrix corresponds to the identity matrix as the code is systematic. The tiles are shown as groups of 4 by 4 adjacent binary values. Each horizontal space between two groups of four horizontally adjacent binary values is a space between different tiles. Each vertical space between two groups of four vertically adjacent binary values is a space between different tiles.

The codes in FIGS. 1 to 3 may be obtained using XOR operations only. Only XOR operations may be used during the discovery process of the codes. The discovery process may comprise verifying the codes to check that they have the properties suitable for erasure coding and recovery of lost data nodes.

By generating codes in this way, distinct and advantageous codes from those generated by known coding techniques can be found. The codes according to embodiments are not equivalent to codes generated by known coding techniques, such as Reed Solomon coding. In particular, at least one of the B by B tiles in the generator matrix that defines the combination of source data for generating redundant data is not an equivalent representation of a number in GF(2\hat{ }B), i.e. it is not a number in the higher order Galois Field (2\hat{ }B).

As described earlier, the number of columns of tiles in FIGS. 1 to 3 is the same as the number of source nodes and the number of rows of tiles is the same as the number of redundant nodes. The ‘1’ values in the matrix identify which of the substripes of source nodes are combined by XOR operations to generate each substripe of redundant data.

Since the combinations of substripes of source data may be performed with XOR operations only, the source data can be provided as one dimensional vectors and coding comprises bit-wise XOR operations between values in the vectors.

Embodiments include a number of related codes to the codes as shown in FIGS. 1 to 3. Accordingly, the redundant nodes according to embodiments are generated in dependence on the codes as shown in FIGS. 1 to 3, and not necessarily according to the codes as specifically shown in FIGS. 1 to 3.

In particular, the generator matrix can be decreased in size by removing any entire row of tiles and/or any entire column of tiles and therefore adapted for use when there is a lower number of source and/or redundant nodes.

Embodiments include a number of related generator matrices to those shown in FIGS. 1 to 3. For example:
Within each entire row of tiles, the order of rows in the tiles is arbitrary. That is to say, the position of any two rows in a tile can be swapped. The change in order of the rows should be made in each of the tiles in the entire row of tiles.
Within each entire column of tiles, the order of columns in the tiles are arbitrary.

That is to say, the position of any two columns in a tile can be swapped. The change in order of the columns should be made in each of the tiles in the entire column of tiles.

Embodiments also include equivalent generator matrices to the generator matrices described above. For example, in FIGS. 1 to 3, the number of columns of tiles corresponds to the number of source nodes and the number of rows of tiles corresponds to the number of redundant nodes. Equivalent generator matrices could also be defined in which the number of rows of tiles corresponds to the number of source nodes and the number of columns of tiles corresponds to the number of redundant nodes.

The use of the identity matrices along the top row and left column of the generator matrix is preferable and this is an optimization.

The codes according to embodiments have the property of at least one of the B by B tiles in the generator matrix that defines the combination of substripes of source data for generating substripes of redundant data not being an equivalent representation of a number in GF(2\hat{ }B), i.e. it is not a number in the higher order Galois Field (2\hat{ }B). The codes according to embodiments are therefore distinct from codes in which all of the tiles are an equivalent representation of a number in GF(2\hat{ }B).

Preferably, in the codes according to embodiments, the number of substripes of source data that at least one of the redundant nodes is generated in dependence on is exactly eleven. That is to say, the generator matrix according to embodiments comprises one or more tiles that each comprise exactly eleven ‘1’ values.

Preferably, in the codes according to embodiments, the number of substripes of source data that the redundant nodes are generated in dependence on is greater than the maximum number of substripes of source data that the redundant nodes can be generated in dependence on when a code in which each tile is an equivalent representation of a number in GF(2\hat{ }B) is used. That is to say, the generator matrix according to embodiments comprises more ‘1’ values than a generator matrix in which each tile is an equivalent representation of a number in GF(2\hat{ }B).

Preferably, in codes according to embodiments, the at least one of the tiles that is not a representation of a number in GF(2\hat{ }B) comprises values that determine to generate at least one of the substripes of redundant data in dependence on a larger number of substripes of source data than the maximum number of substripes of source data that a substripe of redundant data can be determined to be generated in dependence on by a different generator matrix that entirely consists of tiles of binary values with each of the tiles being a representation of a number in GF(2\hat{ }B).

Preferably, in codes according to embodiments, the at least one of the tiles that is not a representation of a number in GF(2\hat{ }B) comprises more ‘1’ values, i.e. values that determine a substripe of source data to be used to generate a substripe of redundant data, than possible when a code in which each tile is an equivalent representation of a number in GF(2\hat{ }B) is used. No swapping of the rows or columns of the tile can therefore produce an equivalent representation of a number in GF(2\hat{ }B).

Preferably, in codes according to embodiments, the total number of substripes of source data that all of the substripes of redundant data are generated in dependence on is larger than the maximum number of substripes of source data that all of the substripes of redundant data can be determined to be generated in dependence on by a different generator matrix that entirely consists of tiles of binary values with each of the tiles being a representation of a number in GF(2\hat{ }B).

Advantageously, codes according to embodiments provide improved performance over RS codes.

When Reed-Solomon coding is used in a field where the minimum amount of bits encoded per node is 4 and there is more than one redundant node, the maximum number of source and data nodes is 15. For example, there may be 10 nodes of source data and 5 nodes of redundant data. Another example is 11 nodes of source data and 4 nodes of redundant data. Another example is 12 nodes of source data and 3 nodes of redundant data.

According to embodiments, when 4 by 4 tiles are used, which, similar to the Reed-Solomon code described above, has 4 bits encoded per node, a given number of redundant nodes can support more nodes of source data. Up to three redundant nodes can support up to 15 nodes of source data. When there are 15 nodes of source data and three nodes of redundant data, the coding is MDS since any three nodes can be recovered using XOR operations only. This is an improvement over RS coding that can only support 12 nodes of source data with three nodes of redundant data.

In particular, with the codes according the embodiments:
3 nodes of redundant data can support up to 15 nodes of source data;
4 nodes of redundant data can support up to 13 nodes of source data; and
5 nodes of redundant data can support up to 12 nodes of source data.

The codes can also be adapted for use with a lower number of source nodes and/or redundant nodes by not using any of the rows of tiles or columns of tiles in FIGS. 1 to 3.

For example, not using any one of the rows of tiles in FIG. 1 provides a code in which 2 nodes of redundant data support 15 nodes of source data. This is also an improvement over RS coding with the same minimum bits to encode.

In addition, operations with the codes are advantageously performed using XOR operations only. Accordingly, only XOR operations are required and no multiplication or division calculations are required.

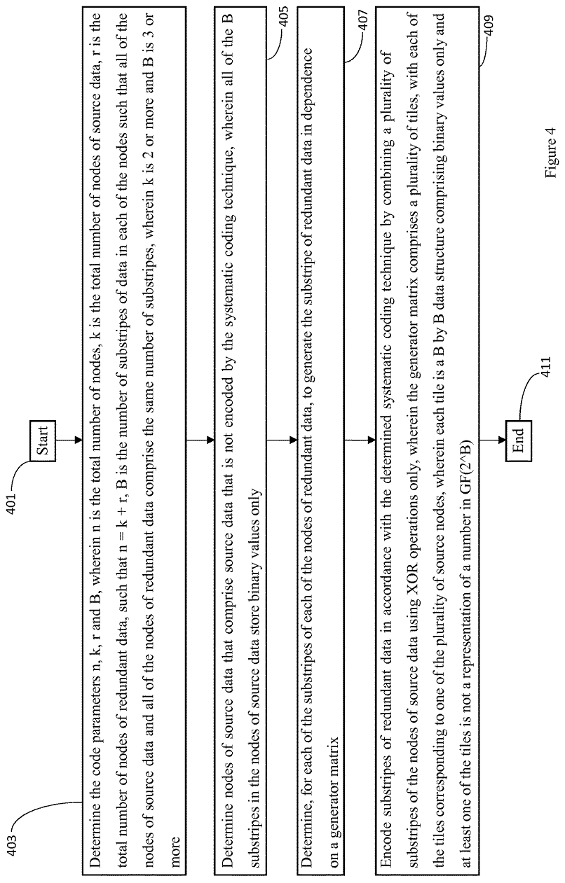

FIG. 4 is a flowchart of a process for determining how to encode data in accordance with a systematic coding technique and encoding data in accordance with the determined systematic coding technique according to an embodiment.

In step 401, the process begins.

In step 403, the code parameters n, k, r and B are determined, wherein n is the total number of nodes, k is the total number of nodes of source data, r is the total number of nodes of redundant data, such that n=k+r, B is the number of substripes of data in each of the nodes such that all of the nodes of source data and all of the nodes of redundant data comprise the same number of substripes, wherein k is 2 or more and B is 3 or more.

In step 405, nodes of source data that comprise source data that is not encoded by the systematic coding technique are determined, wherein all of the B substripes in the nodes of source data store binary values only.

In step 407, for each of the substripes of each of the nodes of redundant data, it is determined to generate the substripe of redundant data in dependence on a generator matrix.

In step 409, substripes of redundant data are encoded in accordance with the determined systematic coding technique by combining a plurality of substripes of the nodes of source data using XOR operations only, wherein the generator matrix comprises a plurality of tiles, with each of the tiles corresponding to one of the plurality of source nodes, wherein each tile is a B by B data structure comprising binary values only and at least one of the tiles is not a representation of a number in GF(2\hat{ }B).

In step 411, the process ends.

Embodiments of the invention also include a number of further modifications and variations to the embodiments as described above.

Although examples of codes with tiles of size 4 by 4 have been provided, embodiments include the use of other tile sizes. The tile size is B by B, where B is 2 or more, and preferably B is 3 or more.

Codes according embodiments can be found by a search using a computational algorithm that only uses XOR operations during its discovery process.

The codes according to embodiments are preferably used for coding data stored in nodes of a data storage system. The coding techniques of embodiments can also be used in other applications in which redundant data nodes or packets are generated, including network coding and data transmission in general.

The flow charts and descriptions thereof herein should not be understood to prescribe a fixed order of performing the method steps described therein. Rather, the method steps may be performed in any order that is practicable. Although the present invention has been described in connection with specific exemplary embodiments, it should be understood that various changes, substitutions, and alterations apparent to those skilled in the art can be made to the disclosed embodiments without departing from the spirit and scope of the invention as set forth in the appended claims.

Methods and processes described herein can be embodied as code (e.g., software code) and/or data. Such code and data can be stored on one or more computer-readable media, which may include any device or medium that can store code and/or data for use by a computer system. When a computer system reads and executes the code and/or data stored on a computer-readable medium, the computer system performs the methods and processes embodied as data structures and code stored within the computer-readable storage medium. In certain embodiments, one or more of the steps of the methods and processes described herein can be performed by a processor (e.g., a processor of a computer system or data storage system). It should be appreciated by those skilled in the art that computer-readable media include removable and non-removable structures/devices that can be used for storage of information, such as computer-readable instructions, data structures, program modules, and other data used by a computing system/environment. A computer-readable medium includes, but is not limited to, volatile memory such as random access memories (RAM, DRAM, SRAM); and non-volatile memory such as flash memory, various read-only-memories (ROM, PROM, EPROM, EEPROM), magnetic and ferromagnetic/ferroelectric memories (MRAM, FeRAM), phase-change memory (such as 3D XPoint) and magnetic and optical storage devices (hard drives, magnetic tape, CDs, DVDs); network devices; or other media now known or later developed that is capable of storing computer-readable information/data. Computer-readable media should not be construed or interpreted to include any propagating signals.

1. A method for determining how to encode data in accordance with a systematic coding technique and encoding data in accordance with the determined systematic coding technique, the method comprising:
determining the code parameters n, k, r and B, wherein n is the total number of nodes, k is the total number of nodes of source data, r is the total number of nodes of redundant data, such that n=k+r, B is the number of substripes of data in each of the nodes such that all of the nodes of source data and all of the nodes of redundant data comprise the same number of substripes, wherein k is 2 or more and B is 3 or more;
determining nodes of source data that comprise source data that is not encoded by the systematic coding technique, wherein all of the B substripes in the nodes of source data store binary values only; and
for each of the substripes of each of the nodes of redundant data, determining to generate the substripe of redundant data in dependence on a generator matrix; and
encoding substripes of redundant data in accordance with the determined systematic coding technique by combining a plurality of substripes of the nodes of source data using XOR operations only;
wherein the generator matrix comprises a plurality of tiles, with each of the tiles corresponding to one of the plurality of source nodes, wherein each tile is a B by B data structure comprising binary values only and at least one of the tiles is not a representation of a number in GF(2\hat{ }B).

2. The method according to claim 1, wherein said at least one of the tiles that is not a representation of a number in GF(2\hat{ }B) comprises values that determine to generate one of the redundant nodes in dependence on exactly eleven substripes of source data.

3. The method according to claim 1 or 2, wherein said at least one of the tiles that is not a representation of a number in GF(2\hat{ }B) comprises values that determine to generate at least one of the substripes of redundant data in dependence on a larger number of substripes of source data than the maximum number of substripes of source data that a substripe of redundant data can be determined to be generated in dependence on by a different generator matrix that entirely consists of tiles of binary values with all of the tiles being a representation of a number in GF(2\hat{ }B).

4. The method according to claim 1, wherein the total number of substripes of source data that all of the substripes of redundant data are generated in dependence on is larger than the maximum number of substripes of source data that all of the substripes of redundant data can be determined to be generated in dependence on by a different generator matrix that entirely consists of tiles of binary values with all of the tiles being a representation of a number in GF(2\hat{ }B).

5. A method for determining how to encode data in accordance with a systematic coding technique and encoding data in accordance with the determined systematic coding technique, the method comprising:
determining the code parameters n, k, r and B, wherein n is the total number of nodes, k is the total number of nodes of source data, r is the total number of nodes of redundant data, such that n=k+r, B is the number of substripes of data in each of the nodes such that all of the nodes of source data and all of the nodes of redundant data comprise the same number of substripes, wherein k is 2 or more and B is 3 or more;
determining nodes of source data that comprise source data that is not encoded by the systematic coding technique, wherein all of the B substripes in the nodes of source data store binary values only; and
for each of the substripes of each of the nodes of redundant data, determining to generate the substripe of redundant data in dependence on a generator matrix; and
encoding substripes of redundant data in accordance with the determined systematic coding technique by combining a plurality of substripes of the nodes of source data using XOR operations only;
wherein, for at least one of the nodes of redundant data, the node of redundant data is generated in dependence on exactly eleven substripes of source data.

6. A method for determining how to encode data in accordance with a systematic coding technique and encoding data in accordance with the determined systematic coding technique, the method comprising:
determining the code parameters n, k, r and B, wherein n is the total number of nodes, k is the total number of nodes of source data, r is the total number of nodes of redundant data, such that n=k+r, B is the number of substripes of data in each of the nodes such that all of the nodes of source data and all of the nodes of redundant data comprise the same number of substripes, wherein k is 2 or more and B is 3 or more;
determining nodes of source data that comprise source data that is not encoded by the systematic coding technique, wherein all of the B substripes in the nodes of source data store binary values only; and
for each of the substripes of each of the nodes of redundant data, determining to generate the substripe of redundant data in dependence on a generator matrix; and
encoding substripes of redundant data in accordance with the determined systematic coding technique by combining a plurality of substripes of the nodes of source data using XOR operations only;
wherein, for at least one of the substripes of redundant data, the substripe of redundant data is generated in dependence on a larger number of substripes of source data than the maximum number of substripes of source data that a substripe of redundant data can be determined to be generated in dependence on by a different generator matrix that entirely consists of tiles of binary values with all of the tiles being a representation of a number in GF(2\hat{ }B).

7. A method for determining how to encode data in accordance with a systematic coding technique and encoding data in accordance with the determined systematic coding technique, the method comprising:
determining the code parameters n, k, r and B, wherein n is the total number of nodes, k is the total number of nodes of source data, r is the total number of nodes of redundant data, such that n=k+r, B is the number of substripes of data in each of the nodes such that all of the nodes of source data and all of the nodes of redundant data comprise the same number of substripes, wherein k is 2 or more and B is 3 or more;
determining nodes of source data that comprise source data that is not encoded by the systematic coding technique, wherein all of the B substripes in the nodes of source data store binary values only; and
for each of the substripes of each of the nodes of redundant data, determining to generate the substripe of redundant data in dependence on a generator matrix; and
encoding substripes of redundant data in accordance with the determined systematic coding technique by combining a plurality of substripes of the nodes of source data using XOR operations only;
wherein the total number of substripes of source data that all of the substripes of redundant data are generated in dependence on is larger than the maximum number of substripes of source data that all of the substripes of redundant data can be determined to be generated in dependence on by a different generator matrix that entirely consists of tiles of binary values with all of the tiles being a representation of a number in GF(2\hat{ }B).

8. The method according to claim 1, wherein B=4.

9. The method according to claim 1, wherein:
k≤15, preferably k=15;
r is 2 or 3; and the tiles are dependent on any k columns and any r rows of:

| | | | | | | | | | | | | | | |
|---|---|---|---|---|---|---|---|---|---|---|---|---|---|---|
| 1000 | 1000 | 1000 | 1000 | 1000 | 1000 | 1000 | 1000 | 1000 | 1000 | 1000 | 1000 | 1000 | 1000 | 1000 |
| 0100 | 0100 | 0100 | 0100 | 0100 | 0100 | 0100 | 0100 | 0100 | 0100 | 0100 | 0100 | 0100 | 0100 | 0100 |
| 0010 | 0010 | 0010 | 0010 | 0010 | 0010 | 0010 | 0010 | 0010 | 0010 | 0010 | 0010 | 0010 | 0010 | 0010 |
| 0001 | 0001 | 0001 | 0001 | 0001 | 0001 | 0001 | 0001 | 0001 | 0001 | 0001 | 0001 | 0001 | 0001 | 0001 |
| 1000 | 0100 | 1100 | 0010 | 1010 | 0110 | 1110 | 0001 | 1001 | 0101 | 1101 | 0011 | 1011 | 0111 | 1111 |
| 0100 | 1100 | 1000 | 0001 | 0101 | 1101 | 1001 | 0011 | 0111 | 1111 | 1011 | 0010 | 0110 | 1110 | 1010 |
| 0010 | 0001 | 0011 | 0110 | 0100 | 0111 | 0101 | 1101 | 1111 | 1100 | 1110 | 1011 | 1001 | 1010 | 1000 |
| 0001 | 0011 | 0010 | 1101 | 1100 | 1110 | 1111 | 1011 | 1010 | 1000 | 1001 | 0110 | 0111 | 0101 | 0100 |
| 1000 | 1100 | 0100 | 0110 | 1110 | 1010 | 0010 | 1011 | 0011 | 0111 | 1111 | 1101 | 0101 | 0001 | 1001 |
| 0100 | 1000 | 1100 | 1101 | 1001 | 0101 | 0001 | 0110 | 0010 | 1110 | 1010 | 1011 | 1111 | 0011 | 0111 |
| 0010 | 0011 | 0001 | 0111 | 0101 | 0100 | 0110 | 1001 | 1011 | 1010 | 1000 | 1110 | 1100 | 1101 | 1111 |
| 0001 | 0010 | 0011 | 1110 | 1111 | 1100 | 1101 | 0111 | 0110 | 0101 | 0100 | 1001 | 1000 | 1011 | 1010 |

wherein each column of tiles corresponds to a different one of the source nodes and each row of tiles corresponds to a different one of the redundant nodes.

10. The method according to claim 1, wherein:
k≤13, preferably k=13;
2≤r≤4; and the tiles are dependent on any k columns and any r rows of:

| | | | | | | | | | | | | |
|---|---|---|---|---|---|---|---|---|---|---|---|---|
| 1000 | 1000 | 1000 | 1000 | 1000 | 1000 | 1000 | 1000 | 1000 | 1000 | 1000 | 1000 | 1000 |
| 0100 | 0100 | 0100 | 0100 | 0100 | 0100 | 0100 | 0100 | 0100 | 0100 | 0100 | 0100 | 0100 |
| 0010 | 0010 | 0010 | 0010 | 0010 | 0010 | 0010 | 0010 | 0010 | 0010 | 0010 | 0010 | 0010 |
| 0001 | 0001 | 0001 | 0001 | 0001 | 0001 | 0001 | 0001 | 0001 | 0001 | 0001 | 0001 | 0001 |
| 1000 | 0100 | 1100 | 0010 | 1010 | 0110 | 1110 | 0001 | 1001 | 0101 | 1101 | 0011 | 1011 |
| 0100 | 1100 | 1000 | 0001 | 0101 | 1101 | 1001 | 0011 | 0111 | 1111 | 1011 | 0010 | 0110 |
| 0010 | 0001 | 0011 | 0110 | 0100 | 0111 | 0101 | 1101 | 1111 | 1100 | 1110 | 1011 | 1001 |
| 0001 | 0011 | 0010 | 1101 | 1100 | 1110 | 1111 | 1011 | 1010 | 1000 | 1001 | 0110 | 0111 |
| 1000 | 1110 | 1011 | 0001 | 0011 | 1100 | 0101 | 0111 | 1010 | 1101 | 0110 | 0100 | 0010 |
| 0100 | 1001 | 0110 | 0011 | 0010 | 1000 | 1111 | 1110 | 0101 | 1011 | 1101 | 1100 | 0001 |
| 0010 | 0101 | 1001 | 1101 | 1011 | 0011 | 1100 | 1010 | 0100 | 1110 | 0111 | 0001 | 0110 |
| 0001 | 1111 | 0111 | 1011 | 0110 | 0010 | 1000 | 0101 | 1100 | 1001 | 1110 | 0011 | 1101 |
| 1000 | 0011 | 0110 | 1011 | 1001 | 1101 | 0100 | 0010 | 1111 | 1110 | 0101 | 1010 | 1100 |
| 0100 | 0010 | 1101 | 0110 | 0111 | 1011 | 1100 | 0001 | 1010 | 1001 | 1111 | 0101 | 1000 |
| 0010 | 1011 | 0111 | 1001 | 1111 | 1110 | 0001 | 0110 | 1000 | 0101 | 1100 | 0100 | 0011 |
| 0001 | 0110 | 1110 | 0111 | 1010 | 1001 | 0011 | 1101 | 0100 | 1111 | 1000 | 1100 | 0010 |

wherein each column of tiles corresponds to a different one of the source nodes and each row of tiles corresponds to a different one of the redundant nodes.

11. The method according to claim 1, wherein:
k≤13, preferably k=13;
2≤r≤5; and the tiles are dependent on any k columns and any r rows of:

| | | | | | | | | | | | |
|---|---|---|---|---|---|---|---|---|---|---|---|
| 1000 | 1000 | 1000 | 1000 | 1000 | 1000 | 1000 | 1000 | 1000 | 1000 | 1000 | 1000 |
| 0100 | 0100 | 0100 | 0100 | 0100 | 0100 | 0100 | 0100 | 0100 | 0100 | 0100 | 0100 |
| 0010 | 0010 | 0010 | 0010 | 0010 | 0010 | 0010 | 0010 | 0010 | 0010 | 0010 | 0010 |
| 0001 | 0001 | 0001 | 0001 | 0001 | 0001 | 0001 | 0001 | 0001 | 0001 | 0001 | 0001 |
| 1000 | 0100 | 1100 | 0010 | 1010 | 0110 | 1110 | 0001 | 1001 | 0101 | 1101 | 0011 |
| 0100 | 1100 | 1000 | 0001 | 0101 | 1101 | 1001 | 0011 | 0111 | 1111 | 1011 | 0010 |
| 0010 | 0001 | 0011 | 0110 | 0100 | 0111 | 0101 | 1101 | 1111 | 1100 | 1110 | 1011 |
| 0001 | 0011 | 0010 | 1101 | 1100 | 1110 | 1111 | 1011 | 1010 | 1000 | 1001 | 0110 |
| 1000 | 0011 | 0110 | 1011 | 1001 | 1101 | 0100 | 0010 | 1111 | 1110 | 0101 | 1010 |
| 0100 | 0010 | 1101 | 0110 | 0111 | 1011 | 1100 | 0001 | 1010 | 1001 | 1111 | 0101 |
| 0010 | 1011 | 0111 | 1001 | 1111 | 1110 | 0001 | 0110 | 1000 | 0101 | 1100 | 0100 |
| 0001 | 0110 | 1110 | 0111 | 1010 | 1001 | 0011 | 1101 | 0100 | 1111 | 1000 | 1100 |
| 1000 | 1110 | 1011 | 0001 | 0011 | 1100 | 0101 | 0111 | 1010 | 1101 | 0110 | 0100 |
| 0100 | 1001 | 0110 | 0011 | 0010 | 1000 | 1111 | 1110 | 0101 | 1011 | 1101 | 1100 |
| 0010 | 0101 | 1001 | 1101 | 1011 | 0011 | 1100 | 1010 | 0100 | 1110 | 0111 | 0001 |
| 0001 | 1111 | 0111 | 1011 | 0110 | 0010 | 1000 | 0101 | 1100 | 1001 | 1110 | 0011 |
| 1000 | 0110 | 0111 | 1111 | 0101 | 0001 | 1100 | 1001 | 1110 | 1011 | 0010 | 1101 |
| 0100 | 1101 | 1110 | 1010 | 1111 | 0011 | 1000 | 0111 | 1001 | 0110 | 0001 | 1011 |
| 0010 | 0111 | 1010 | 1000 | 1100 | 1101 | 0011 | 1111 | 0101 | 1001 | 0110 | 1110 |
| 0001 | 1110 | 0101 | 0100 | 1000 | 1011 | 0010 | 1010 | 1111 | 0111 | 1101 | 1001 |

wherein each column of tiles corresponds to a different one of the source nodes and each row of tiles corresponds to a different one of the redundant nodes.

12. A method of generating coded data from source data, the method being equivalent to generating the coded data in dependence on the method of claim 1.

13. The method according to claim 1, wherein the method is computer-implemented.

14. A generator matrix for defining how to generate coded data from source data, the generator matrix defining a code that is equivalent to a code that has been generated by the method according to claim 1.

15. A method of decoding coded data, the method comprising decoding coded data that has been coded according to the method according to claim 1, wherein the method is computer-implemented.

16. The method according to claim 15, wherein the method comprises recovering source data and/or redundant data by performing XOR operations only.

17. The method according to claim 1, further comprising storing the redundant data in a data storage system.

18. (canceled)

19. A computing system configured to perform the method according to claim 1.

20. The computing system according to claim 19, wherein the computing system comprises a data storage system; and
the data storage system comprises a plurality of nodes for storing source and redundant data.

21. The computing system according to claim 20, wherein:
the computing system further comprises a data processing system, wherein the data processing system is separate from the data storage system; and
the processing performed to generate and/or recover source data and/or redundant data is performed in the data processing system.
